(19) United States
(12) Patent Application Publication
(10) Pub. No.: US 2016/0081191 A1
(43) Pub. Date: Mar. 17, 2016

(54) PRINTED CIRCUIT BOARD AND MANUFACTURING METHOD THEREOF

(71) Applicant: SAMSUNG ELECTRO-MECHANICS CO., LTD., Suwon-Si (KR)

(72) Inventors: Jee-Soo MOK, Suwon (KR); Yong-Ho BAEK, Seoul (KR); Young-Gwan KO, Suwon (KR)

(21) Appl. No.: 14/733,245

(22) Filed: Jun. 8, 2015

(30) Foreign Application Priority Data
Sep. 16, 2014 (KR) 10-2014-0123016

(51) Int. Cl. H05K 1/11; H05K 1/18; H05K 3/30; H05K 3/40; H05K 3/02

(52) U.S. Cl. CPC H05K 1/113; H05K 3/4038; H05K 3/022; H05K 3/30; H05K 1/183

(57) ABSTRACT

A printed circuit board and a manufacturing method thereof are disclosed. The printed circuit board in accordance with an aspect of the present invention includes: a base board having a pad formed on one surface thereof; a copper clad laminate laminated on the one surface of the base board and having a cavity formed therein such that the pad is placed within the cavity; and an insulating adhesive layer interposed between the base board and the copper clad laminate in such a way that the pad is exposed

### CROSS-REFERENCE TO RELATED APPLICATIONS

This application claims the benefit of Korean Patent Application No. 10-2014-0123016, filed with the Korean Intellectual Property Office on Sep. 16, 2014, the disclosure of which is incorporated herein by reference in its entirety.

### BACKGROUND

1. Technical Field

The present invention relates to a printed circuit board and a method of manufacturing the same.

2. Background Art

Most of active/passive devices are mounted on a substrate by use of the surface mount technology (SMT) in the conventional electronics manufacturing industry. However, with the trend of electronic products becoming smaller, an increasing number of new packaging technologies have been developed to embed the active/passive devices in the substrate.

For active/passive device-embedded substrate, an economical manufacturing process is possible by integrating various active/passive devices in an organic substrate, and this kind of packaging technology may be applied to modularized products, contributing to making the products smaller.

In addition to the advantages of multi-functionality and compact size, the active/passive device-embedded substrate has an aspect of higher performance, owing to providing a solution for improving the reliability issue that is often raised during an electrical connection of the device using wire bonding and a solder ball, which are used in a flip chip and a ball grid array, respectively.

The related art of the present invention is disclosed in Korean Patent Publication No. 10-2010-0059010 (laid open on Jun. 4, 2010).

### SUMMARY

An embodiment of the present invention provides a printed circuit board and a manufacturing method thereof in which a copper clad laminate having a cavity formed therein is laminated on a base board having a pad pre-processed thereon through an insulating adhesive layer.

Here, the insulating adhesive layer may be laminated first on one surface of the base board having the pad formed thereon and then have a portion thereof corresponding to the pad removed to allow the pad to be exposed.

### BRIEF DESCRIPTION OF DRAWINGS

FIG. 1 shows a printed circuit board in accordance with an embodiment of the present invention.

FIG. 2 is a flow diagram showing a method of manufacturing a printed circuit board in accordance with an embodiment of the present invention.

FIG. 3, FIG. 4, FIG. 5, FIG. 6, FIG. 7 and FIG. 8 show main steps of the method of manufacturing a printed circuit board in accordance with an embodiment of the present invention.

### DETAILED DESCRIPTION

Hereinafter, a printed circuit board and a manufacturing method thereof in accordance with the present invention will be described with reference to the accompanying drawings. In describing the present invention with reference to the accompanying drawings, any identical or corresponding elements will be assigned with same reference numerals, and their description will not be provided redundantly.

When one element is described to be “coupled” to another element, it does not refer to a physical, direct contact between these elements only, but it shall also include the possibility of yet another element being interposed between these elements and each of these elements being in contact with said yet another element.

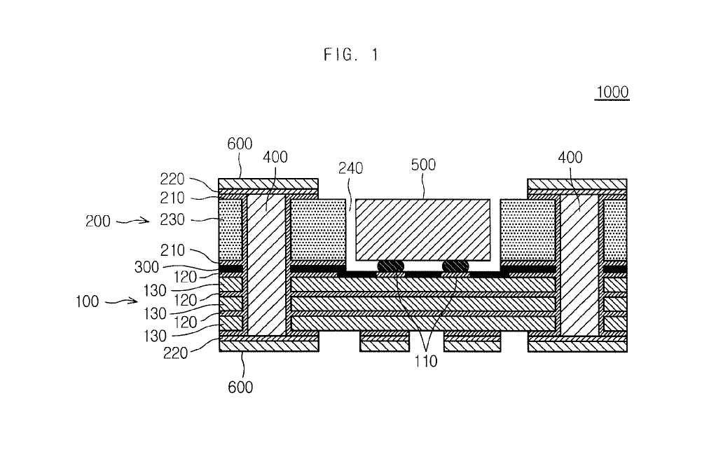

FIG. 1 shows a printed circuit board in accordance with an embodiment of the present invention.

As illustrated in FIG. 1, a printed circuit board 1000 in accordance with an embodiment of the present invention includes a base board 100, a copper clad laminate 200 and an insulating adhesive layer 300 and may further include a via hole 400 and an electronic device 500.

The base board 100, which has a pad 110 formed on one surface thereof, may be constituted with at least a pair of an inner circuit layer 120 and an insulation layer 130. That is, the base board 100 may be formed by successively laminating a metal layer, which is for forming the inner circuit layer 120, and the insulation layer 130.

The inner circuit layer 120 may be formed by processing, for example, exposing and etching, the metal layer laminated on the insulation layer 130. For instance, the inner circuit layer 120 may be formed by a subtractive process, an additive process or a modified semi additive process, depending on the manufacturing process.

Moreover, an outer circuit layer 220 may be formed on the other surface of the base board 100 by use of an etching process using photolithography or an additive process (plating process).

Here, the pad 110, which is a conductor that is electrically connected with the electronic device 500, may be a part of the inner circuit layer 120. Moreover, the pad 110 may be connected with the outer circuit layer 220 and/or another inner circuit layer 120 through a separate via (not shown).

The copper clad laminate 200, which is laminated on the one surface of the base board 100 and has a cavity 240 formed therein such that the pad 110 is placed within the cavity 240, is a laminated plate in which a copper foil 210 is laminated on both sides of a polyimide-based insulation layer 230.

In such a case, the outer circuit layer 220 may be formed on a surface of the copper clad laminate 200 that is opposite to a surface of the copper clad laminate 200 with which the base board 100 is in contact. Moreover, a surface of the outer circuit layer 220 forms an insulated coating structure through a solder resist layer 600 to protect the outer circuit layer 220.

Since a prepreg commonly used for forming the cavity 240 in the printed circuit board 1000 is formed by impregnating and hardening a thermosetting resin in a base material such as glass fiber until a B-stage (i.e., a state until the resin is semi-hardened), warpage may be occurred due to a cure shrinkage until the prepreg is completely hardened.

Meanwhile, the above-described copper clad laminate 200 itself is modularized, and the cure shrinkage thereof that is observed in the prepreg may be minimized because the insulation layer 230 is in a C-stage (i.e., a state that the resin is completely hardened).

Here, the cavity 240 is a space for installing the electronic component 500 in the copper clad laminate 200 and may be formed by a punching process, using a CNC drill or a mold, or a laser drill (CO₂ or YAG).

The insulating adhesive layer 300, which is interposed between the base board 100 and the copper clad laminate 200 such that the pad 110 is exposed, may not only adhere the base board 100 and the copper clad laminate 200 to each other but also insulate the base board 100 and the copper clad laminate 200 from each other.

In such a case, the insulating adhesive layer 300 may be formed by coating a thermosetting flame-resistant epoxy adhesive on an insulation film such as a polyimide film, but it shall be appreciated that the formation of the insulating adhesive layer 300 is not restricted to what is described herein and that the insulating adhesive layer 300 may be formed in various configurations as long as it has both adhesive and insulating properties.

In the printed circuit board 1000 in accordance with the present embodiment, the insulating adhesive layer 300 may be laminated on the one surface of the base board 100 having the pad 110 formed thereon and then have a portion thereof corresponding to the pad 110 removed to allow the pad 110 to be exposed.

That is, by laminating the insulating adhesive layer 300 on the one surface of the base board 100 so as to cover the pad 110 and then removing a portion thereof through a follow-up process, for example, chemical etching, the pad 110 may be exposed within the cavity 240.

As described above, the pad 110 is formed on the one surface of the base board 100, and a separate solder resist needs to be formed on the pad 110 in order to protect the pad 110 during the manufacturing process of the printed circuit board 1000.

However, with the printed circuit board 1000 in accordance with the present embodiment, no separate solder resist is used, but the insulating adhesive layer 300 performs the function of the solder resist for protecting the pad 110, and the pad 110 is exposed from the insulating adhesive layer 300 through the follow-up process.

Accordingly, the printed circuit board 1000 in accordance with the present embodiment may be manufactured without a process for forming a protective layer for protecting the pad 110 and thus may be readily manufactured through a shorter process.

The via hole 400 penetrates the base board 100 and the copper clad laminate 200 integrally to allow the base board 100 and the copper clad laminate 200 to be electrically conductive, and thus may allow a top and a bottom of the printed circuit board 1000 of the present embodiment to be electrically conductive.

Specifically, by being integrally connected from the outer circuit layer 220 of the copper clad laminate 200 to the outer circuit layer 220 of the base board 100 and being further connected to the inner circuit layer 120, the via hole 400 may allow the top and bottom of the printed circuit board 1000 of the present embodiment to be electrically conductive.

In such a case, the via hole 400 may be formed by copper-plating an inner wall thereof, filling an insulating resin therein and then cover-plating the exposed insulating resin, but it shall be appreciated that the present invention is not restricted to what is described herein and that there may be various other structures for allowing the top and bottom to be electrically conductive in the printed circuit board 1000.

The electronic component 500, which is installed in the cavity 240 and is electrically connected with the pad 110, may be an active device, such as an integrated circuit chip, or a passive device, such as a capacitor and an inductor. In such a case, the electronic component 500 may have a terminal formed thereon for electrical connection with the pad 110.

Since the printed circuit board 1000 in accordance with the present embodiment has the cavity 240 formed at a portion of the copper clad laminate 200 and has the electronic component 500 installed in the cavity 240, it is readily possible to allow an electronic product using the printed circuit board 1000 of the present embodiment to be smaller and thinner.

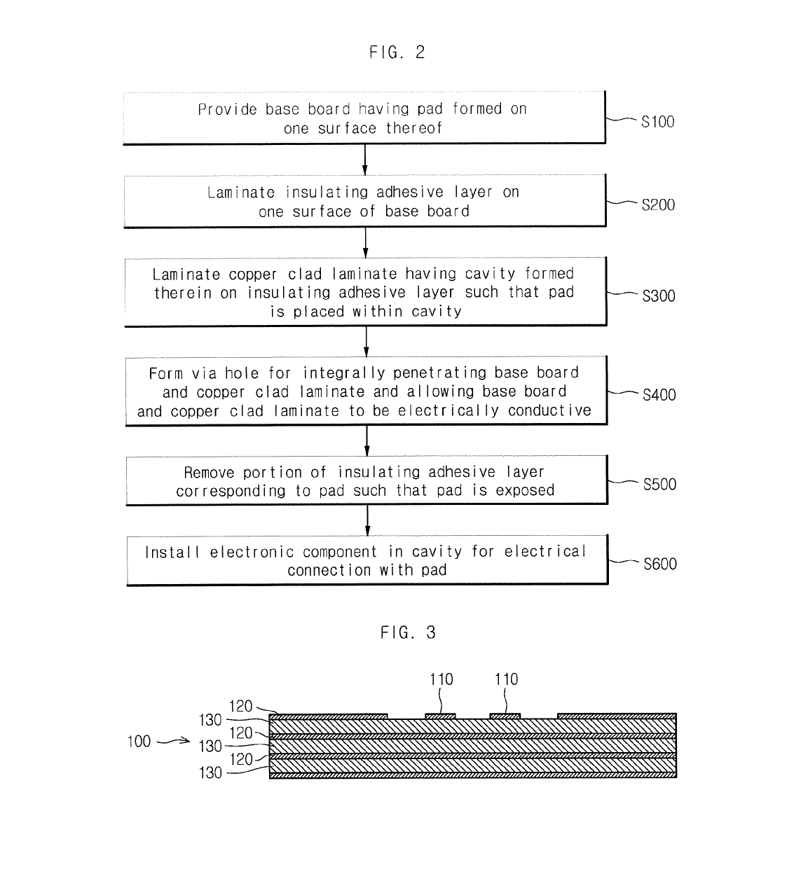

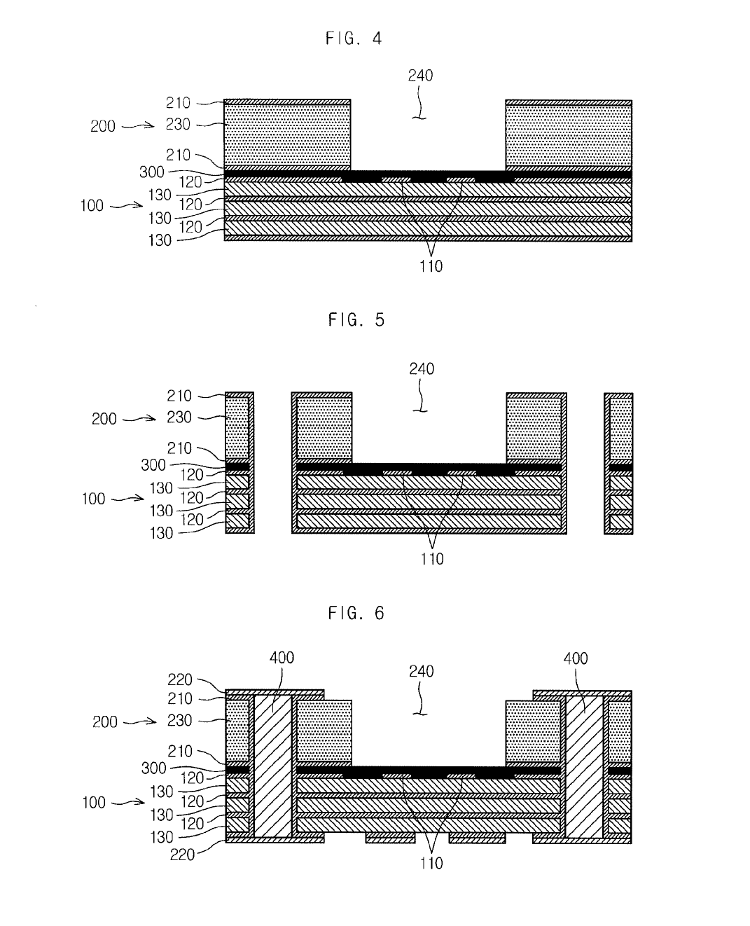

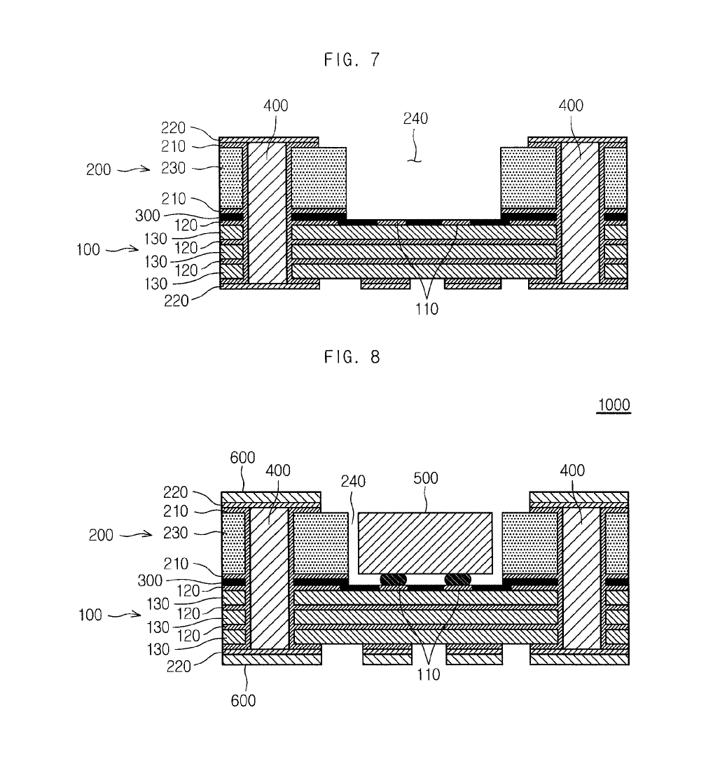

FIG. 2 is a flow diagram showing a method of manufacturing a printed circuit board in accordance with an embodiment of the present invention. FIG. 3, FIG. 4, FIG. 5, FIG. 6, FIG. 7 and FIG. 8 show main steps of the method of manufacturing a printed circuit board in accordance with an embodiment of the present invention.

As illustrated in FIG. 2 to FIG. 8, the method of manufacturing a printed circuit board in accordance with an embodiment of the present invention starts with providing a base board 100 having a pad 110 formed on one surface thereof (S100, FIG. 3).

Here, the base hoard 100 may be constituted with at least a pair of an inner circuit layer 120 and an insulation layer 130. That is, the base board 100 may be formed by successively laminating a metal layer, which is for forming the inner circuit layer 120, and the insulation layer 130, and the inner circuit layer 120 may be formed by processing, for example, exposing and etching, the metal layer laminated on the insulation layer 130.

Here, the pad 110, which is a conductor that is electrically connected with an electronic device 500, may be a part of the inner circuit layer 120. Moreover, the pad 110 may be connected with the outer circuit layer 220 and/or another inner circuit layer 120 through a separate via (not shown).

Then, an insulating adhesive layer 300 is laminated on the one surface of the base board 100 (S200, FIG. 4). Here, the insulating adhesive layer 300 is interposed between the base board 100 and a copper clad laminate 200 such that the base board 100 and the copper clad laminate 200 are not only adhered to each other but also insulated from each other.

Next, the copper clad laminate 200 having a cavity 240 formed therein is laminated on the insulating adhesive layer 300 in such a way that the pad 110 is placed within the cavity 240 (S300, FIG. 4). Here, the copper clad laminate 200 is a laminated plate in which a copper foil 210 is laminated on both sides of a polyimide-based insulation layer 230.

Here, the cavity 240 is a space for installing the electronic component 500 in the copper clad laminate 200 and may be formed by a punching process, using a CNC drill or a mold, or a laser drill (CO₂ or YAG).

Since a prepreg commonly used for forming the cavity 240 in the printed circuit board 1000 is formed by impregnating and hardening a thermosetting resin in a base material such as glass fiber until a B-stage (i.e., a state until the resin is semi-hardened), warpage may be occurred due to a cure shrinkage until the prepreg is completely hardened.

Meanwhile, the above-described copper clad laminate 200 itself is modularized, and the cure shrinkage thereof that is observed in the prepreg may be minimized because the insulation layer 230 is in a C-stage (i.e., a state that the resin is completely hardened).

The method of manufacturing a printed circuit board in accordance with the present embodiment may further include, after the S300 step, forming a via hole 400 for integrally penetrating the base board 100 and the copper clad laminate 200 and allowing the base board 100 and the copper clad laminate 200 to be electrically conductive (S400, FIG. 5 and FIG. 6).

Specifically, by being integrally connected from an outer circuit layer 220 of the copper clad laminate 200 to an outer circuit layer 220 of the base board 100 and being further connected to the inner circuit layer 120, the via hole 400 may allow the top and bottom of the printed circuit board 1000 of the present embodiment to be electrically conductive.

As illustrated in FIG. 6, the via hole 400 may be formed by copper-plating an inner wall thereof, filling an insulating resin therein and then cover-plating the exposed insulating resin, but it shall be appreciated that the present invention is not restricted to what is illustrated herein and that there may be various other structures for allowing the top and bottom to be electrically conductive in the printed circuit board 1000.

Moreover, as shown in FIG. 6, in the method of manufacturing a printed circuit board in accordance with the present embodiment, the outer circuit layer 220 may be formed on the other surface of the base board 100 and on a surface of the copper clad laminate 200 that is opposite to a surface of the copper clad laminate 200 with which the base board 100 is in contact, after the S300 step.

The method of manufacturing a printed circuit board in accordance with the present embodiment may further include, after the S400 step, removing a portion of the insulating adhesive layer 300 corresponding to the pad 110 such that the pad 110 is exposed (S500, FIG. 7).

That is, by laminating the insulating adhesive layer 300 on the one surface of the base board 100 so as to cover the pad 110 and then removing a portion thereof through a follow-up process, for example, chemical etching, the pad 110 may be exposed within the cavity 240.

As described herein, with the method of manufacturing a printed circuit board in accordance with the present embodiment, no separate solder resist is used, but the insulating adhesive layer 300 performs the function of the solder resist for protecting the pad 110, and the pad 110 is exposed from the insulating adhesive layer 300 through the follow-up process.

Accordingly, the method of manufacturing a printed circuit board in accordance with the present embodiment may skip a process for forming a protective layer for protecting the pad 110, and thus the printed circuit board 1000 may be readily manufactured through a shorter process.

The method of manufacturing a printed circuit board in accordance with the present embodiment may further include, after the S500 step, installing the electronic component 500 in the cavity 240 for electrical connection with the pad 110 (S600, FIG. 8).

The electronic component 500 may be an active device, such as an integrated circuit chip, or a passive device, such as a capacitor and an inductor and may have a terminal formed thereon for electrical connection with the pad 110.

Since the method of manufacturing a printed circuit board in accordance with the present embodiment has the cavity 240 formed at a portion of the copper clad laminate 200 and has the electronic component 500 installed in the cavity 240, it is readily possible to allow an electronic product using the printed circuit board 1000 to be smaller and thinner.

Meanwhile, as shown in FIG. 8, a surface of the outer circuit layer 220 forms an insulated coating structure through a solder resist layer 600 to protect the outer circuit layer 220.

Although a certain embodiment of the present invention has been described above, it shall be appreciated that there can be a variety of permutations and modifications of the present invention by those who are ordinarily skilled in the art to which the present invention pertains without departing from the technical ideas and scope of the present invention, which shall be defined by the appended claims. It shall be also appreciated that a large number of other embodiments than the above-described embodiment are included in the claims of the present invention.

What is claimed is:

1. A printed circuit board comprising:
a base board having a pad formed on one surface thereof;
a copper clad laminate laminated on the one surface of the base board and having a cavity formed therein such that the pad is placed within the cavity; and
an insulating adhesive layer interposed between the base board and the copper clad laminate in such a way that the pad is exposed.

2. The printed circuit board of claim 1, wherein the insulating adhesive layer is laminated on the one surface of the base board having the pad formed thereon and is formed to have a portion thereof corresponding to the pad removed to allow the pad to be exposed.

3. The printed circuit board of claim 2, further comprising a via hole integrally penetrating the base board and the copper clad laminate and allowing the base board and the copper clad laminate to be electrically conductive.

4. The printed circuit board of claim 3, further comprising an electronic component being embedded in the cavity and being electrically connected with the pad.

5. A method of manufacturing a printed circuit board, comprising:
providing a base board having a pad formed on one surface thereof;
laminating an insulating adhesive layer on the one surface of the base board; and
laminating a copper clad laminate having a cavity formed therein on the insulating adhesive layer in such a way that the pad is placed within the cavity.

6. The method of claim 5, further comprising, after the laminating of the copper clad laminate, forming a via hole integrally penetrating the base board and the copper clad laminate and allowing the base board and the copper clad laminate to be electrically conductive.

7. The method of claim 6, further comprising, after the forming of the via hole, removing a portion of the insulating adhesive layer corresponding to the pad in such a way that the pad is exposed.

8. The method of claim 7, further comprising, after the removing of the portion of the insulating adhesive layer corresponding to the pad, embedding an electronic component in the cavity for electrical connection with the pad.
